(19) United States
(12) Patent Application Publication
(10) Pub. No.: US 2026/0215047 A1
(43) Pub. Date: Jul. 23, 2026

(54) DIE METALLIZATION FOR DENSE PACKED ARRAYS

(71) Applicant: Lumileds LLC, San Jose, CA (US)

(72) Inventors: Jeffrey Vincent DiMaria, San Jose, CA (US); Oleg Borisovich Shchekin, San Francisco, CA (US); Yu-Chen Shen, Sunnyvale, CA (US); Florent Gregoire Monestier, Kerkrade (NL)

(21) Appl. No.: 19/139,216

(22) PCT Filed: Dec. 13, 2023
(86) PCT No.: PCT/US2023/083753

§ 371 Date: Jun. 13, 2025

Related U.S. Application Data
(60) Provisional application No. 63/433,095, filed on Dec. 16, 2022.

(51) Int. Cl. H10H 20/857; H10H 20/01; H10H 20/85; H10H 29/85

(52) U.S. Cl. CPC H10H 20/857; H10H 20/0364; H10H 20/8502; H10H 29/858

(57) ABSTRACT

An illumination device is provided multiple light emitting diode (LED) dies are connected in series through an inter-mediary metallization layer. Cathode under bump metallization (nUBM) has an L shape and anode UBM (pUBM) has a rectangular shape. The combined nUBM and pUBM shape is square and are arranged to maintain a constant distance therebetween. The leg of the L shape of the nUBM of one die is connected to the metallization layer, which is connected to the pUBM of the adjacent die. The metallization layer maintains a constant distance from the pUBM of the one die. The connection between the metallization layer and the nUBM is localized to the one die.

### PRIORITY CLAIM

This application claims the benefit of priority to U.S. Provisional Patent Application Ser. No. 63/433,095, filed Dec. 16, 2022, which is incorporated herein by reference in its entirety.

### FIELD OF THE DISCLOSURE

The present disclosure relates to die and tile metallization. In particular, embodiments are directed to die and tile metallization in dense light emitting diode (LED) structures.

### BACKGROUND OF THE DISCLOSURE

There is ongoing effort to improve multi-die lamp architectures. In particular, it is desirable to improve die thermal resistance and sharpness of luminance cut-off while maintaining luminance uniformity along an array of LEDs in multi-die lamp architectures.

### BRIEF DESCRIPTION OF THE DRAWINGS

FIG. 1 shows an illumination apparatus, in accordance with some examples.

FIG. 2A illustrates a top view of a single-die package architecture, in accordance with some examples.

FIG. 2B illustrates a cross-sectional view of the single-die package architecture of FIG. 2A, in accordance with some examples.

FIG. 3A illustrates a top view of a single-die package architecture, in accordance with some examples.

FIG. 3B illustrates a cross-sectional view of the single-die package architecture of FIG. 3A, in accordance with some examples.

FIG. 4A illustrates a top view of a multi-die package architecture, in accordance with some examples.

FIG. 4B illustrates a top view of metallization of the multi-die package architecture of FIG. 4A, in accordance with some examples.

FIG. 4C illustrates a cross-sectional view of the multi-die package architecture of FIG. 4A, in accordance with some examples.

FIG. 5A illustrates a top view of a multi-die package architecture, in accordance with some examples.

FIG. 5B illustrates a top view of metallization of the multi-die package architecture of FIG. 5A, in accordance with some examples.

FIG. 5C illustrates a cross-sectional view of the multi-die package architecture of FIG. 5A, in accordance with some examples.

FIG. 6 illustrates an example of an electronic device in accordance with some embodiments.

FIG. 7 illustrates an example lighting system, according to some embodiments.

FIG. 8 illustrates an example hardware arrangement for implementing the above disclosed subject matter, according to some embodiments.

FIG. 9 illustrates an example hardware arrangement for implementing the above disclosed subject matter, according to some embodiments.

FIG. 10 illustrates an example method of fabricating an LED device, according to some embodiments.

### DETAILED DESCRIPTION

Die and tile metallization in dense LED structures and methods of fabricating LED structures are provided. The LED structures may be used in a variety of applications, such as flashes for camera applications, display applications, and vehicular applications.

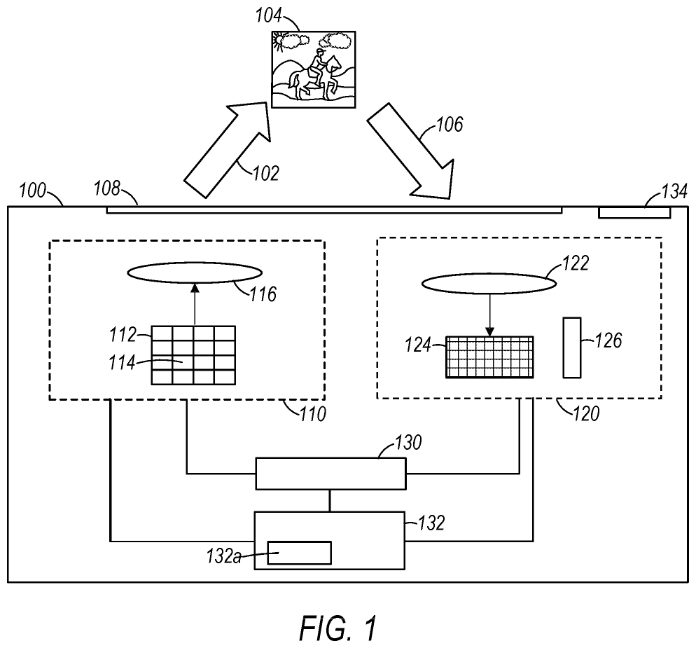

FIG. 1 shows an illumination apparatus 100, in accordance with some examples. The illumination apparatus 100 may be, for example, a smart phone or standalone camera that contains an adaptive LED light source. The illumination apparatus 100 may include both a light source 110 and a camera 120. The camera 120 may capture an image of a scene 104 during an exposure duration of the camera 120, whether or not the scene 104 is illuminated by the light source 110. A processor 130 may be used to control various functions of the light source 110 and the camera 120, including whether or not a shutter is open in an opening 108 of a housing of the illumination apparatus 100.

The opening 108 may be a single opening as shown in FIG. 1 or may include multiple separate openings. Similarly, the shutter may be a single shutter that covers both the light source 110 and the camera 120 or may include multiple separate shutters that covers only one of the light source 110 or the camera 120 and are individually controllable by the processor 130.

The illumination apparatus 100 may include one or more LED arrays 112. Each of the one or more LED arrays 112 may include a plurality of LEDs 114 that may produce light during at least a portion of the exposure duration of the camera 120. Each of the one or more LED arrays 112 may contain segmented LEDs 114 in which the LEDs 114 are divided into a grid of light emitting areas (the LEDs 114) and non-light emitting areas (between the LEDs 114). In some embodiments, the effect of the non-light emitting areas on the image captured using the one or more LED arrays 112 may be compensated for by moving the one or more LED arrays 112 and/or at least one lens 116 using one or more actuators during the exposure duration of the scene 104 to shift the LEDs 114 slightly to illuminate the areas of the scene 104 that would be subject to the non-light emitting areas.

Each of the LEDs 114 may be formed using one or more inorganic semiconductor materials (e.g., binary compounds such as gallium arsenide (GaAs) or gallium nitride (GaN), ternary compounds such as aluminum gallium arsenide (AlGaAs), quaternary compounds such as indium gallium phosphide (InGaAsP)), or other suitable materials. The LEDs 114 are typically either III-V materials (defined by columns of the Periodic Table) or II-VI materials. Each of the LEDs 114 may emit light in the visible spectrum (about 400 nm to about 780 nm) or may also emit light in the infrared spectrum (above about 780 nm). In some embodiments, one or more other layers, such as a phosphor layer may be disposed on each of the one or more LED arrays 112 to convert the light from the LEDs 114 into white (or another color) light. LEDs 114 in a particular LED array 112 that emit light in the infrared spectrum may be, for example, interspersed with LEDs 114 may emit light in the visible spectrum, or each type of LED (visible emitter/infrared emitter) may be disposed on different sections of the particular LED array 112. Alternatively, each LED array 112 may only emit light in either the visible spectrum or the infrared spectrum; separate (one or more) LED arrays may be used to emit light in the infrared spectrum, each of the individual LED array 112, LEDs 114 and/or LED segments controllable by the processor 130.

Each of the one or more LED arrays 112 may be, for example, micro-LED array, the latter of which includes thousands to millions of microscopic LEDs 114 that may emit light and that may be individually controlled or controlled in groups of pixels (e.g., 5×5 groups of pixels).

MicroLEDs are relatively small (e.g., <0.01 mm on a side) compared to typical LEDs and may provide monochromatic or multi-chromatic light, typically red, green, or blue using inorganic semiconductor material such as that indicated above.

The light source 110 may include at least one lens 116 and/or other optical elements such as reflectors. The lens 116 and/or other optical elements may direct the light emitted by the one or more LED arrays 112 toward the scene 104 as illumination 102.

The camera 120 may sense light at least the wavelength or wavelengths emitted by the one or more LED arrays 112. Similar to the light source 110, the camera 120 may include optics (e.g., at least one camera lens 122) that are able to collect reflected light 106 of the illumination 102 that is reflected from and/or emitted by the scene 104. The camera lens 122 may direct the reflected light 106 onto a multi-pixel sensor 124 (also referred to as a light sensor) to form an image of the scene 104 on the multi-pixel sensor 124.

The processor 130 may receive a data signal that represents the image of the scene 104. The processor 130 may additionally control and drive the LEDs 114 in the one or more LED arrays 112 via one or more drivers 132.

For example, the processor 130 may optionally control one or more LEDs 114 in the one or more LED arrays 112 independent of another one or more LEDs 114 in the one or more LED arrays 112, so as to illuminate the scene in a specified manner In addition, one or more detectors 126 may be incorporated in the camera 120. In other embodiments, instead of being incorporated in the camera 120, the one or more detectors 126 may be incorporated in one or more different areas, such as the light source 110 or elsewhere close to the camera 120. The one or more detectors 126 may include multiple different sensors to sense visible and/or infrared light (e.g., from the scene 104), and may further sense the ambient light and/or variations/flicker in the ambient light in addition to reception of the reflected light from the LEDs 114. The multi-pixel sensor 124 of the camera 120 may be of higher resolution than the sensors of the one or more detectors 126 to obtain an image of the scene with a desired resolution.

The sensors of the one or more detectors 126 may have one or more segments (that are able to sense the same wavelength/range of wavelengths or different wavelength/range of wavelengths), similar to the LED arrays 112. In some embodiments, if multiple detectors are used, one or more of the detectors may detect visible wavelengths and one or more of the detectors may detect infrared wavelengths; like the one or more LED arrays 112, the one or more detectors 126 may be individually controllable by the processor 130.

In some embodiments, instead of, or in addition to, being provided in the camera 120, one or more of the sensors of the one or more detectors 126 may be provided in the light source 110. In some embodiments, the light source 110 and the camera 120 may be integrated in a single module, while in other embodiments, the light source 110 and the camera 120 may be separate modules that are disposed on a PCB. In other embodiments, the light source 110 and the camera 120 may be attached to different PCBs-for example, as the camera 120 may be thicker than the light source 110, which may result in design issues if the light source 110 and the camera 120 are attached to the same PCB. In the latter embodiment, multiple openings may be present in the housing at least one of which may be eliminated with the use of an integrated light source 110 and camera 120.

The LEDs 114 may be driven using a direct current (DC) driver or pulse width modulation (PWM). Using DC driving may encounter color differences if the segmented one or more LED arrays 112 is driven at different current densities, while PWM driving may generate artifacts due to ambient lighting conditions. The flicker sensor, if present, may sense the variation of artificial lighting at the wall current frequency or electronic ballasts frequencies (e.g., 50 Hz or 60 Hz or an integral multiple thereof), in addition to the phase of the flicker. The camera sensor is then tuned to an integration time of an integral multiple of the time period (1/f) or triggered at the phase where the illumination changes most slowly (minimum or maximum intensity, with the maximum intensity preferred for signal-to-noise ratio considerations). The LEDs 114 may be driven using a PWM whose phase shift varies between LEDs 114 to reduce potential current surge issues. As shown, one or more drivers 132 may be used to drive the LEDs 114 in the one or more LED arrays 112, as well as other components, such as the actuators.

The illumination apparatus 100 may also include an input device 134, for example, a user-activated input device such as a button that is depressed to take a picture. The light source 110 and camera 120 may be disposed in a single housing.

LEDs can be used in the illumination apparatus 100 shown in FIG. 1 to form different types of displays, LED matrices and light engines including adaptive automotive headlights, augmented reality (AR), virtual reality (VR), or mixed-reality (MR) headsets, smart glasses, and displays for mobile phones, smart watches, monitors and TVs. The individual LED pixels in these architectures may have an area of few square millimeters down to few square micrometers depending on the matrix or display size and pixel-per-inch requirements.

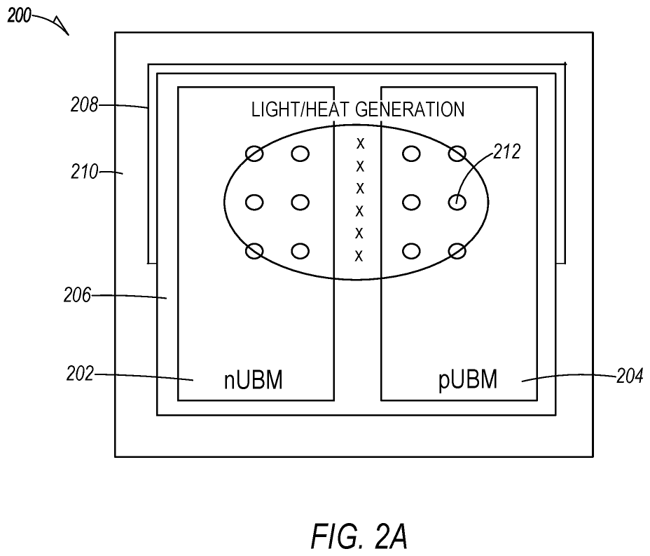

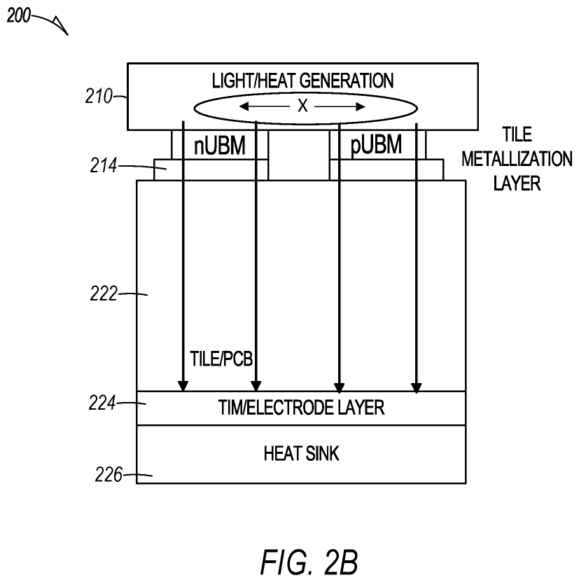

It may be desirable to improve the total system optical efficiency for each of the different types of applications. In particular, the optical efficiency of applications for multi-die packages that provide illumination for sustained periods of time may be relatively low unless carefully designed. FIG. 2A illustrates a top view of a single-die package architecture, in accordance with some examples. FIG. 2B illustrates a cross-sectional view of the single-die package architecture of FIG. 2A, in accordance with some examples. The package architecture 200 shown in FIGS. 2A and 2B illustrates only a single LED die 210 for clarity. The LED die 210 may contain a semiconductor stack 206 that may be fabricated by combining n-and p-type semiconductors (e.g., the above III-V semiconductors) on a substrate (wafer) of sapphire or silicon carbide (SiC), among others. Various layers may be deposited and processed on the substrate during fabrication of the LED. The surface of the substrate may be pretreated to anneal, etch, polish, etc. the surface prior to deposition of the various layers.

In general, the various layers of an LED may be fabricated using epitaxial semiconductor deposition (e.g., metal organic chemical vapor deposition) to deposit one or more semiconductor layers, metal deposition (e.g., by sputtering, plating, or evaporation), oxide growth, as well as etching, liftoff, and cleaning, among other operations. The semiconductor deposition may be used to create an LED with an active region in which electron-hole recombination occurs and the light from the LED is generated. The active region may be, for example, one or more quantum wells. Metal contacts may be used to drive provide current to the n-and p-type semiconductors from integrated circuits (ICs) (such as drivers) of a backplane on which the LED is disposed.

End contacts 208 and center contacts 212 may be fabricated to make electrical contact with different layers of the semiconductor stack 206.

The LED anode may be electrically coupled to an anode under bump metallization (UBM) (pUBM) 204 and the cathode electrically coupled to a cathode UBM (nUBM) 202. Note that the positions of the nUBM 202 and the pUBM 204 may be exchanged in different embodiments. The nUBM 202 and the pUBM 204 may be patterned and formed from a metal, such as copper (Cu), nickel (Ni), gold (Au), silver (Ag), and/or titanium (Ti), for example, which may be deposited on the LED die 210.

As shown in FIG. 2B, the pUBM 204 and the nUBM 202 may be electrically connected to a patterned tile metallization layer 214 that is disposed on a tile 222 (also referred to as a submount). The electrical connection may be formed by direct contact (e.g., thermocompression bonding) or through a solder and reflow process whereby the solder wets to both metal interfaces and forms a solid joint upon cooling. The tile metallization layer 214 may be formed from a metal, such as Cu, which may be the same as, or different from, the material(s) used to form the nUBM 202 and the pUBM 204. The tile metallization layer 214 may entirely overlap the pUBM 204 and the nUBM 202 to ensure electrical contact therebetween.

The tile 222 may be formed from FR4, a ceramic, or aluminum nitride (AlN), for example. The tile 222 may be disposed on a Thermal Interface Material (TIM)/electrode layer 224, which may include a metal, such as those above, and may further include thermal epoxy or grease, for example. The TIM/electrode layer 224 may act as an electrode layer, connecting the tile 222 to a heat sink 226 formed, for example, from Al.

As shown in FIGS. 2A and 2B, the nUBM 202 and the pUBM 204 are disposed on adjacent sides of the LED die 210 and alternates from left to right along the linear array of the LED die 210. In this die orientation, significant current may flow into and generate heat in the gap between the nUBM 202 and the pUBM 204. This may lead to heat generated in the LED die 210 to radiate laterally along the LED die 210 before being able to be transmitted to the heat sink 226. The lateral conduction distance (e.g., several hundred um), however, may be one or more orders of magnitude greater than the vertical conduction distance (e.g., a few um). That is, for the heat to flow out of the LED die 210 into the submount, the heat may travel a significant distance laterally (e.g., more than about 100 μm) through relatively thin metal sheets (e.g., about 1 μm thick×about 1000 μm) to the nUBM 202 and the pUBM 204. Heat generated in such a region can be considered to experience a high thermal resistance and may lead to excessive heat generation in localized regions, reducing the optical efficiency.

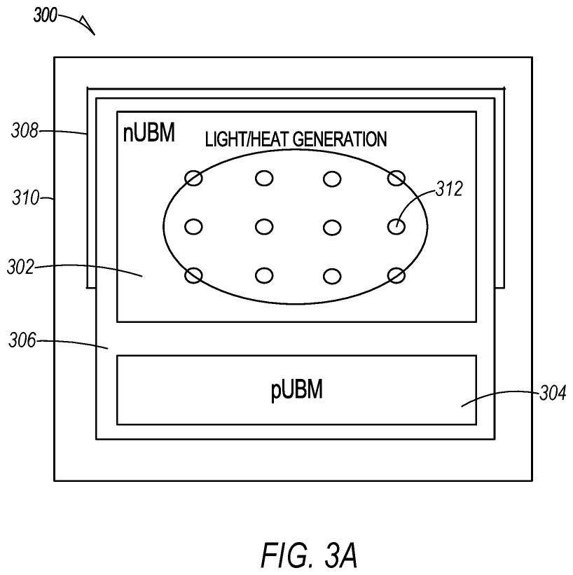

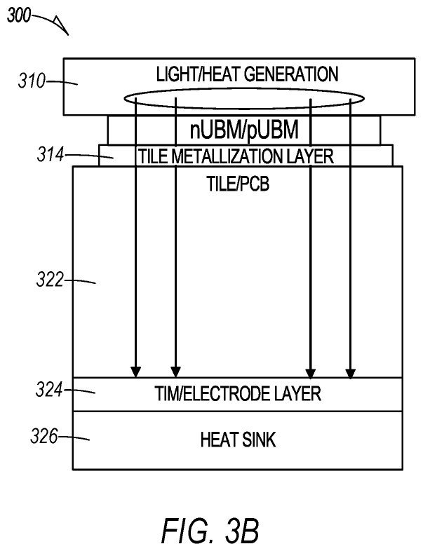

To improve the optical efficiency of, for example, low and high beam headlamps in which one or more LED sources are present, the luminance of the LED sources may be concentrated in one area-for example along a top edge of the LED package. That is the layout of FIG. 2A may be rotated the die orientation such that the nUBM and the pUBM regions of the die are located at the top of the array, where the luminance and current density is highest in this application. FIG. 3A illustrates a top view of a single-die package architecture, in accordance with some examples. FIG. 3B illustrates a cross-sectional view of the single-die package architecture of FIG. 3A, in accordance with some examples. As above, the package architecture 300 shown in FIGS. 3A and 3B illustrates only a single LED die 310 for clarity. The LED die 310 may contain a semiconductor stack 306. End contacts 308 and center contacts 312 may be fabricated to make electrical contact with different layers of the semiconductor stack 306. The nUBM 302 and the pUBM 304 may be electrically connected to a patterned tile metallization layer 314 that is disposed on a tile 322. The tile metallization layer 314 may entirely overlap the pUBM 304 and the nUBM 302 to ensure electrical contact therebetween. The tile 322 may be disposed on a TIM 324 that connects the tile 322 to a heat sink 326. The materials of the various layers in FIGS. 3A and 3B may be similar to that of FIGS. 2A and 2B. As shown, the luminance of the LED die 310 may be concentrated along the top edge of the LED die 310, which is electrically contacted by the nUBM 302. In various embodiments, the positions of the nUBM 302 and the pUBM 304 may be swapped.

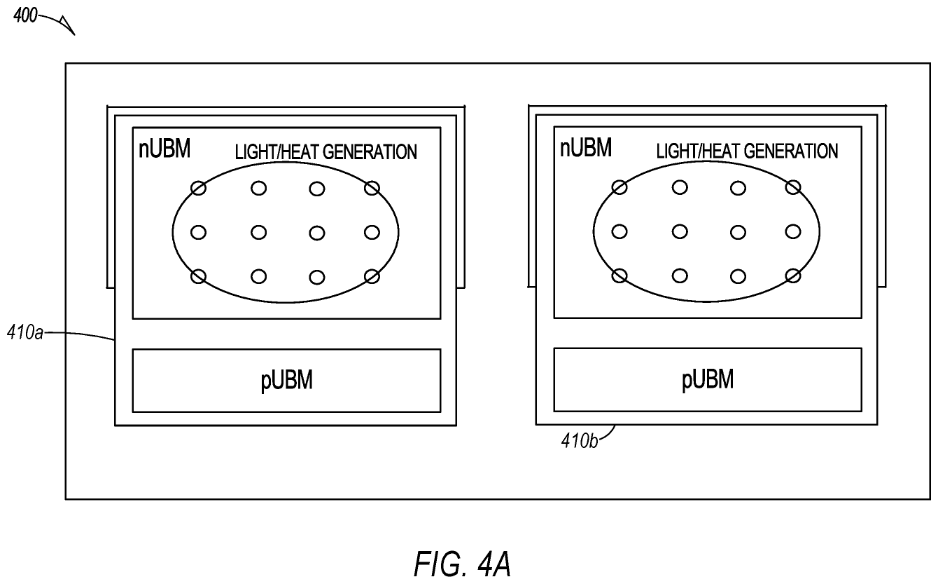

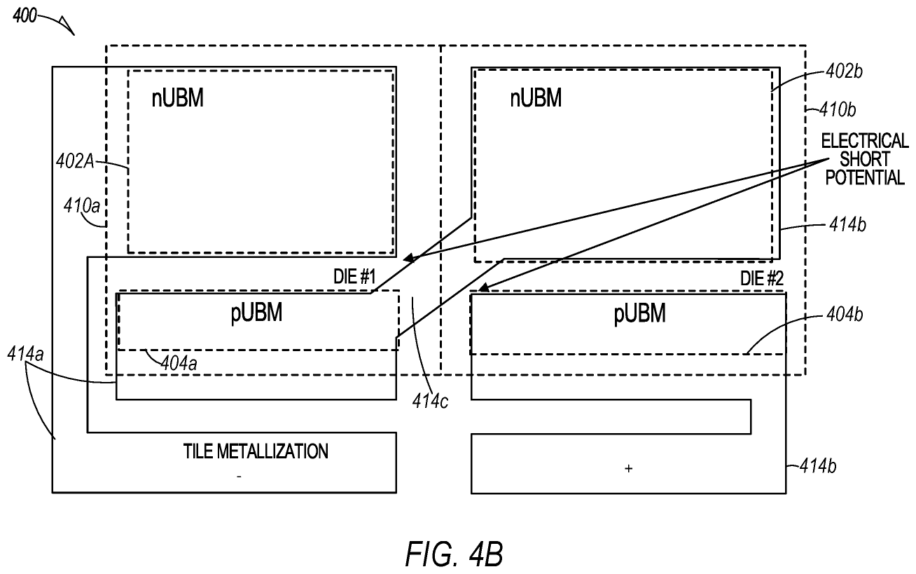

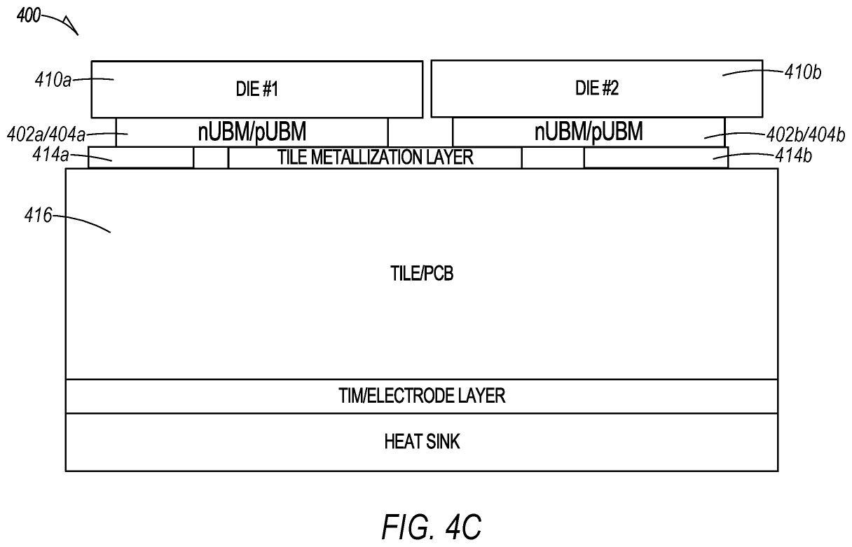

While the configuration shown in FIGS. 3A and 3B may allow the anode (or cathode) to be aligned for improved heat conduction from the region of the LED that generates the most heat, the package architecture 300 shown in FIGS. 3A and 3B, however, may pose other challenges. In particular, the die layout in multi-die package architectures may be constructed so that the LED die is arrayed electrically in series. FIG. 4A illustrates a top view of a multi-die package architecture, in accordance with some examples. In the package architecture 400, the LED dies 410a, 410b are adjacent and relatively close together (e.g., separated by only a few microns) to increase the luminance from the package architecture 400. FIG. 4B illustrates a top view of metallization of the multi-die package architecture of FIG. 4A, in accordance with some examples. FIG. 4C illustrates a cross-sectional view of the multi-die package architecture of FIG. 4A, in accordance with some examples. As can be seen in FIG. 4B, each of the LED dies 410a, 410b in the package architecture 400 is associated with a different nUBM 402a, 402b and pUBM 404a, 404b.

Each of the nUBMs 402a, 402b and pUBMs 404a, 404b is electrically coupled to a patterned tile metallization layer 414a, 414b that overlaps the associated nUBM 402a, 402b and pUBM 404a, 404b. As above, the positions of the nUBM 402a, 402b and the pUBM 404a, 404b of each LED die 410a, 410b may be exchanged.

In the rotated configuration shown in FIGS. 4B and 4C, the spacing between the LED dies 410a, 410b may be limited by the submount trace width and spacing between traces in the metallization layer 414a, 414b at the top of the tile 416, and may be unable to be spaced as closely together as a state-of-the-art configuration without risk of electrical shorting along the diagonal trace 414c that connects the tile metallization layer 414a associated with the pUBM 404a of one LED die 410a with the tile metallization layer 414b associated with the nUBM 402b of the adjacent LED die 410b. As can be seen, the arrangement in FIGS. 4A and 4B may result in a trade-off between improved thermal performance and acceptable luminance uniformity along the multi-die array of the package architecture 400. Since the LED die 410a, 410b may be unable to be placed as closely together, the luminance along the package architecture 400 may be reduced between the LED die 410a, 410b and may thus be undesirable.

The trade-off may be mitigated through co-design of the UBM (both the nUBM and the pUBM) and tile metallization such that the current density and heat generation is highest over a region of the die that has lowest thermal resistance, the highest luminance at the top of the package for optimal contrast and maintains minimized die spacing without compromise of inter-die contrast uniformity. The UBM and tile layout can be modified to allow die to be spaced apart at the same spacing as the configuration of the above figures.

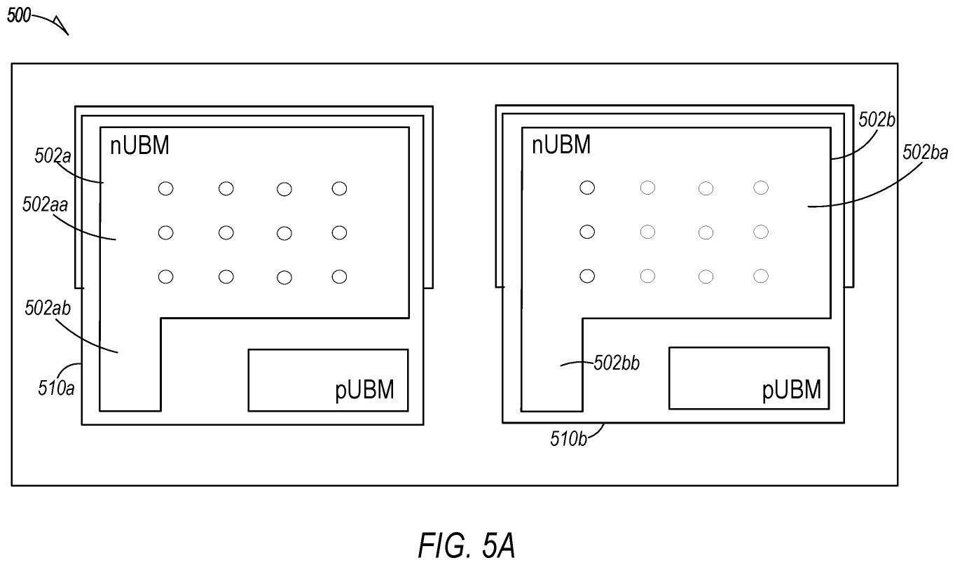

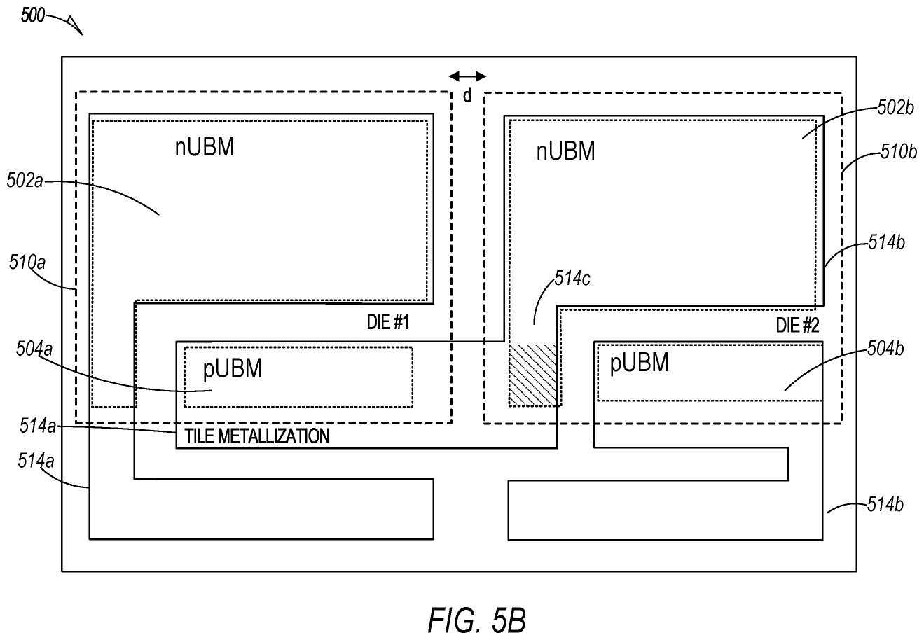

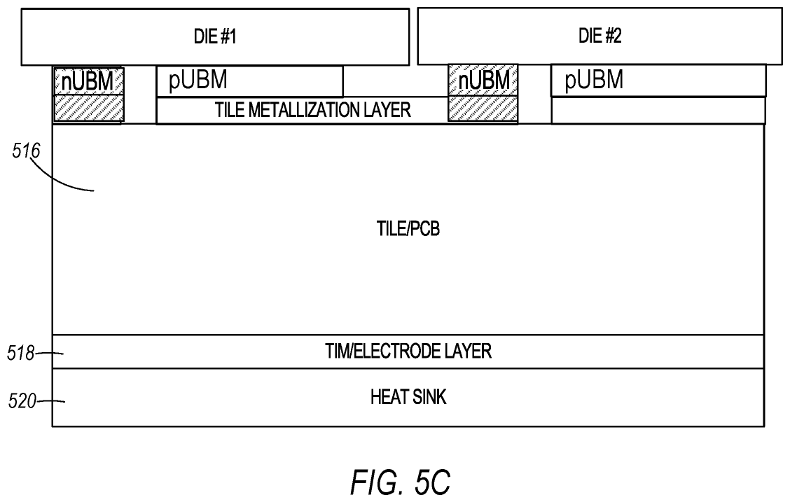

In the package architecture 500, the LED dies 510a, 510b are adjacent and relatively close together (e.g., separated by only a few microns) to increase the light output from the package architecture 500. FIG. 5B illustrates a top view of metallization of the multi-die package architecture of FIG. 5A, in accordance with some examples. FIG. 5C illustrates a cross-sectional view of the multi-die package architecture of FIG. 5A, in accordance with some examples. As can be seen in FIG. 5B, each of the LED dies 510a, 510b in the package architecture 500 is associated with a different nUBM 502a, 502b and pUBM 504a, 504b. Each of the nUBMs 502a, 502b and pUBMs 504a, 504b is electrically coupled to a patterned tile metallization layer 514a, 514b that overlaps the associated nUBM 502a, 502b and pUBM 504a, 504b. As above, the positions of the nUBM 502a, 502b and the pUBM 504a, 504b of each LED die 510a, 510b may be exchanged. The tile metallization layer 514a, 514b may be disposed on a tile 516 on which a TIM 518 is used to connects the tile 516 to a heat sink 520 that dissipates heat from the LED dies 510a, 510b. In some embodiments, solder paste may be used at any electrical interface, e.g., between the nUBM 502a, 502b/pUBM 504a, 504b and tile metallization layer 514a, 514b.

In the configuration shown in FIGS. 5B and 5C, the spacing between the LED dies 510a, 510b is no longer limited by the submount trace width and spacing between traces in the metallization layer 514a, 514b at the top of the tile 516 as no diagonal trace is used to connect the tile metallization layer 514a associated with the pUBM 504a of one LED die 510a with the tile metallization layer 514b associated with the nUBM 502b of the adjacent LED die 510b. Instead, as shown in FIGS. 5A-5C one of the UBMs either (the nUBM 502a, 502b or the pUBM 504a, 504b) may be formed into a substantially L shape (within fabrication tolerance). That is, as shown at least one of the nUBM 502a, 502b or pUBM 504a, 504b may have a relatively larger (rectangular) area 502aa, 502ba and a relatively smaller (rectangular) area 502ab, 502bb that extends at or proximate to one end of the larger area 502aa, 502ba in a direction substantially perpendicular to the larger area 502aa, 502ba. This may move the gap between the tile metallization 514a, 514b beneath the LED die 510a, 510b instead of between the LED dies 510a, 510b. In addition, the tile metallization 514a, 514b connector 514c may extend in a direction perpendicular to the direction of separation d between the LED die 510a, 510b rather than on a diagonal, as shown in FIGS. 4B-4C. In other embodiments, shapes other than an L-shape may be used.

The package architecture 500 may decouple the minimum inter-die spacing from the tile metallization trace gap and width tolerances. As shown, the lateral distances between the tile metallization in the adjacent LED die 510b may remain substantially constant, as may the lateral distances between the nUBM 502b and pUBM 504b in the adjacent LED die 510b. In addition, the area of the nUBM 502a, 502b and the pUBM 504a, 504b may remain essentially the same as the other embodiments described herein. Although an overall shape of the nUBM 502a, 502b or pUBM 504a, 504b within each LED die 510a, 510b in FIGS. 5A-5C substantially forms a square (or rectangle), other overall shapes may result, dependent on the individual shapes of the nUBM 502a, 502b or pUBM 504a, 504b.

Note that only two LED dies are shown in FIGS. 5A-5C.

However, any number of serially-connected LED dies may be used. For example, in automotive applications, for low beam illumination, up to 6 serially-connected LED dies may be used. Thus, the arrangement of FIGS. 5A-5C may be replicated.

Although the UBM sizes are shown as substantially identical in the embodiments above, in other embodiments, the size of the UBM may vary depending on the application. For example, a surface luminance map or heat map may be used to determine the size of the UBM. In some embodiments, the UBM may be sized to cover an area of the LED die in which the luminance is greater than about 60%, greater than about 75%, or at least the area under about 60% to about 80% of the maximum luminance of the LED die. Alternatively, the smaller pad (the UBM) may be about 150 μm, about 100 μm, about 50 μm, or even about 25 μm while the gap between the UBM and the LED die may be about 200 μm, about 100 μm, or about 25 μm. This may permit other shapes to be used for the UBM.

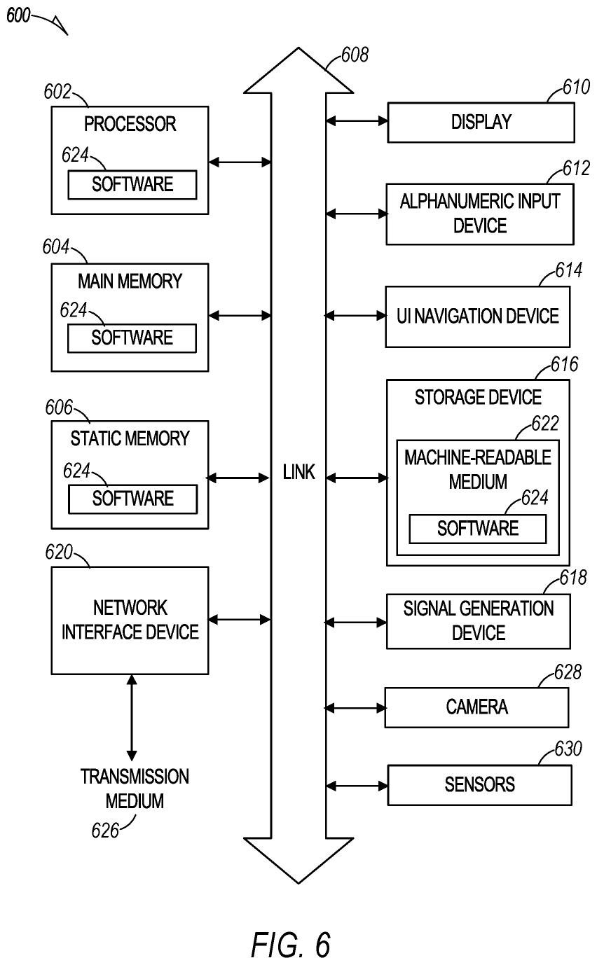

FIG. 6 illustrates an example of an electronic device in accordance with some embodiments. The electronic device 600 may be a mobile device such as a laptop computer (PC), a tablet PC, or a smart phone, for example, an automotive device, or a dedicated electronic apparatus, such as a camera, for example. Various elements may be provided on the PCB indicated above. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The mobile device 600 may include a hardware processor (or equivalently processing circuitry) 602 (e.g., a central processing unit (CPU), a GPU, a hardware processor core, or any combination thereof), a main memory 604 and a static memory 606, some or all of which may communicate with each other via an interlink (e.g., bus) 608. The main memory 604 may contain any or all of removable storage and non-removable storage, volatile memory or non-volatile memory. The mobile device 600 may further include a display 610 such as a video display, an alphanumeric input device 612 (e.g., a keyboard), and a user interface (UI) navigation device 614 (e.g., a mouse). In an example, the display 610, input device 612 and UI navigation device 614 may be a touch screen display. The mobile device 600 may additionally include a storage device (e.g., drive unit) 616, a signal generation device 618 (e.g., a speaker), a network interface device 620, one or more cameras 628, and one or more sensors 630, such as a global positioning system (GPS) sensor, compass, accelerometer, or other sensor such as those described herein. The mobile device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The non-transitory machine readable medium 622 is a tangible medium. A storage device 616 that includes the non-transitory machine-readable medium should not be construed as that either the device or the machine-readable medium is itself incapable of having physical movement. The instructions 624 may also reside, completely or at least partially, within the main memory 604, within static memory 606, and/or within the hardware processor 602 during execution thereof by the mobile device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the mobile device 600 and that cause the mobile device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.15.4 family of standards, a Long Term Evolution (LTE) family of standards, a Universal Mobile Telecommunications System (UMTS) family of standards, peer-to-peer (P2P) networks, a next generation (NG)/5th generation (5G) standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

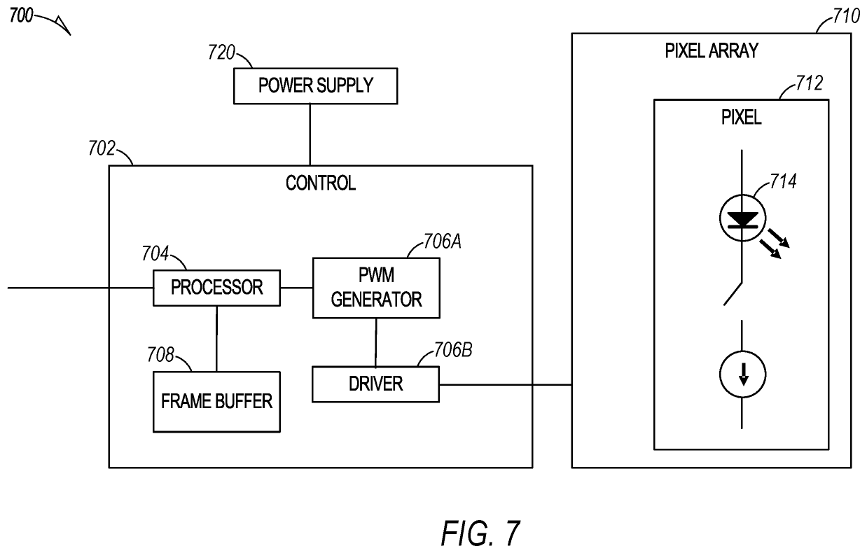

FIG. 7 illustrates an example lighting system, according to some embodiments. As above, some of the elements shown in the lighting system 700 may not be present, while other additional elements may be disposed in the lighting system 700. The lighting system 700 may provide lighting based on an image captured as described in FIG. 1, or may be independently generated based on stored information. For example, the lighting system 700 may include a controller 702 that controls display of an image using a pixel array 710 that contains multiple individual pixels 712.

In some embodiments, some or all of the components described as the controller 702 may be disposed on a backplane such as, for example, a compound metal oxide semiconductor (CMOS) backplane. The controller 702 may be coupled to or include one or more processors 704. The controller 702 may receive image data and inquiries from the one or more processors 704, if external to the controller 702. In this case, the controller 702 may further provide feedback to the one or more processors 704. The one or more processors 704 may receive image data via a digital interface and may process the image data to control a PWM generator 706a, for example, controlling PWM duty cycles and/or turn-on times for causing the lighting system 700 to produce the images indicated by the image data.

The controller 702 may further include a frame buffer 708. The frame buffer 708 may store one or more images prior the one or more processors 704 and store the indications for implementation by the one or more processors 704.

The PWM generator 706a may be controlled by the one or more processors 704 and may produce PWM signals in accordance with the indications. The PWM generator 706a may be connected to a driver 706b to drive the pixel array 710 so that the pixels 712 provide desired intensities of light.

Each pixel 712 may include one or more LEDs 714. The LEDs 714 may be different colors and may be controlled individually or in groups. As shown, the pixel 712 may include, for each pixel 712 or LED 714, a PWM switch, and a current source. The pixel 712 may be driven by the driver 706b.

The PWM signal from the PWM generator 706a may cause the PWM switch to open and close in accordance with the value of the PWM signal. The signal corresponding to the intensities of light may cause the current source to produce a current flow to cause the pixel 712 to produce the corresponding intensities of light.

The lighting system 700 may further include a power supply 720. In some embodiments, the power supply 720 may produce power for the controller 702.

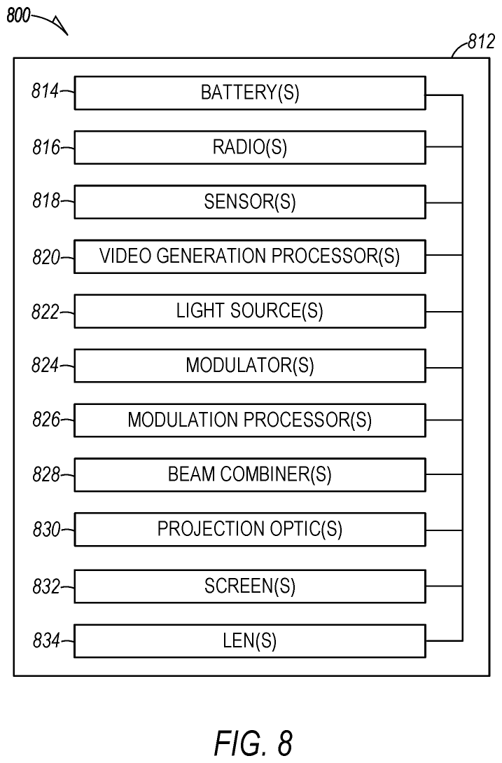

FIG. 8 shows a block diagram of an example of a system, according to some embodiments. The system 800 may provide augmented reality (AR)/virtual reality (VR) functionality using LEDs. The system 800 can include a wearable housing 812, such as a headset or goggles. The housing 812 can mechanically support and house the elements detailed below. In some examples, one or more of the elements detailed below can be included in one or more additional housings that can be separate from the wearable housing 812 and couplable to the wearable housing 812 wirelessly and/or via a wired connection. For example, a separate housing can reduce the weight of wearable goggles, such as by including batteries, radios, and other elements. The housing 812 can include one or more batteries 814, which can electrically power any or all of the elements detailed below. The housing 812 can include circuitry that can electrically couple to an external power supply, such as a wall outlet, to recharge the batteries 814. The housing 812 can include one or more radios 816 to communicate wirelessly with a server or network via a suitable protocol, such as WiFi.

The system 800 can include one or more sensors 818, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 818 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 818 can capture a real-time video image of the surroundings proximate a user.

The system 800 can include one or more video generation processors 820. The one or more video generation processors 820 can receive scene data that represents a three-dimensional scene, such as a set of position coordinates for objects in the scene or a depth map of the scene. This data may be received from a server and/or a storage medium. The one or more video generation processors 820 can receive one or more sensor signals from the one or more sensors 818. In response to the scene data, which represents the surroundings, and at least one sensor signal, which represents the location and/or orientation of the user with respect to the surroundings, the one or more video generation processors 820 can generate at least one video signal that corresponds to a view of the scene. In some examples, the one or more video generation processors 820 can generate two video signals, one for each eye of the user, that represent a view of the scene from a point of view of the left eye and the right eye of the user, respectively. In some examples, the one or more video generation processors 820 can generate more than two video signals and combine the video signals to provide one video signal for both eyes, two video signals for the two eyes, or other combinations.

The system 800 can include one or more light sources 822 that can provide light for a display of the system 800. Suitable light sources 822 can include the LEDs above, for example. The one or more light sources 822 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The system 800 can include one or more modulators 824. The modulators 824 can be implemented in one of at least two configurations. In a first configuration, the modulators 824 can include circuitry that can modulate the light sources 822 directly. For example, the light sources 822 can include an array of light-emitting diodes, and the modulators 824 can directly modulate the electrical power, electrical voltage, and/or electrical current directed to each light-emitting diode in the array to form modulated light. The modulation can be performed in an analog manner and/or a digital manner. In some examples, the light sources 822 can include an array of red light-emitting diodes, an array of green light-emitting diodes, and an array of blue light-emitting diodes, and the modulators 824 can directly modulate the red light-emitting diodes, the green light-emitting diodes, and the blue light-emitting diodes to form the modulated light to produce a specified image.

In a second configuration, the modulators 824 can include a modulation panel, such as a liquid crystal panel. The light sources 822 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 824 can include multiple modulation panels that can modulate different colors of light. For example, the modulators 824 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 824 can receive uniform white light or nearly uniform white light from a white light source, such as a white-light light-emitting diode. The modulation panel can include wavelength-selective filters on each pixel of the modulation panel.

The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 800 can include one or more modulation processors 826, which can receive a video signal, such as from the one or more video generation processors 820, and, in response, can produce an electrical modulation signal. For configurations in which the modulators 824 directly modulate the light sources 822, the electrical modulation signal can drive the light sources 822. For configurations in which the modulators 824 include a modulation panel, the electrical modulation signal can drive the modulation panel.

The system 800 can include one or more beam splitters 828 (and/or beam combiners), which can combine light beams of different colors to form a single multi-color beam. For configurations in which the light sources 822 can include multiple light-emitting diodes of different colors, the system 800 can include one or more wavelength-sensitive (e.g., dichroic) beam splitters 828 that can combine the light of different colors to form a single multi-color beam.

The system 800 can direct the modulated light toward the eyes of the viewer in one of at least two configurations. In a first configuration, the system 800 can function as a projector, and can include suitable projection optics 830 that can project the modulated light onto one or more screens 832. The screens 832 can be located a suitable distance from an eye of the user. The system 800 can optionally include one or more lenses 834 that can locate a virtual image of a screen 832 at a suitable distance from the eye, such as a close-focus distance, such as 500 mm, 750 mm, or another suitable distance. In some examples, the system 800 can include a single screen 832, such that the modulated light can be directed toward both eyes of the user. In some examples, the system 800 can include two screens 832, such that the modulated light from each screen 832 can be directed toward a respective eye of the user. In some examples, the system 800 can include more than two screens 832. In a second configuration, the system 800 can direct the modulated light directly into one or both eyes of a viewer. For example, the projection optics 830 can form an image on a retina of an eye of the user, or an image on each retina of the two eyes of the user.

For some configurations of AR systems, the system 800 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

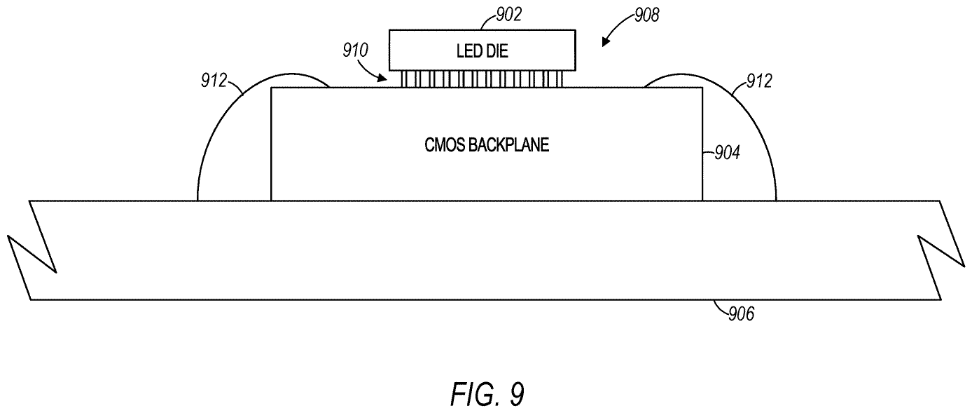

FIG. 9 illustrates an example hardware arrangement for implementing the above disclosed subject matter, according to some embodiments. In particular, the hardware arrangement 900 may include an integrated LED 908. The integrated LED 908 may include an LED die 902 that contains the LED array(s) and a backplane, such as a CMOS backplane 904.

The LED die 902 may be coupled to the CMOS backplane 904 by one or more interconnects 910, where the interconnects 910 may provide for transmission of signals between the LED die 902 and the CMOS backplane 904. The interconnects 910 may comprise one or more solder bump joints, one or more copper pillar bump joints, other types of interconnects known in the art, or some combination thereof.

In some embodiments, the LED die 902 may further include switches and current sources to drive the micro-LED array. In other embodiments, the PWM switches and the current sources may be included in the CMOS backplane 904.

The CMOS backplane 904 may include circuitry to implement the control module and/or the LED power supply. The CMOS backplane 904 may utilize the interconnects 910 to provide the micro-LED array with the PWM signals and the signals for the intensity for causing the micro-LED array to produce light in accordance with the PWM signals and the intensity. Because of the relatively large number and density of connections to drive the micro-LED array compared to standard LED arrays, different embodiments may be used to electrically connect the CMOS backplane 904 and the LED die 902. Either the bonding pad pitch of the CMOS backplane 904 may be the same as the pitch of bonding pads in the micro-LED array, or the bonding pad pitch of the CMOS backplane 904 may be larger than the pitch of bonding pads in the micro-LED array.

The hardware arrangement 900 may further include a PCB 906.

The PCB 906 may include circuitry to implement various functionality described herein. The PCB 906 may be coupled to the CMOS backplane 904. For example, the PCB 906 may be coupled to the CMOS backplane 904 via one or more wire bonds 912. The PCB 906 and the CMOS backplane 904 may exchange image data, power, and/or feedback via the coupling, among other signals.

As shown, the micro-LEDs and circuitry supporting the micro-LED array can be packaged and include a submount or printed circuit board for powering and controlling light production by the micro-LEDs. The PCB supporting the micro-LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the micro-LED array and a power supply, and also provide heat sink functionality.

As above, a variety of applications may be supported by micro-LED arrays. Such applications may include a stand-alone applications to provide general illumination (e.g., within a room or vehicle) or to provide specific images. In addition to devices such as a luminaire, projector, mobile device, the system may be used to provide either augmented reality (AR) and virtual reality (VR)-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data.

Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more micro-LED pixels (groups of micro-LEDs) to display content (AR/VR and/or non-AR/VR) to the user while controlling other micro-LEDs and sensors used in eye tracking to adjust the content displayed.

Content display micro-LEDs may be designed to emit light within the visible band (approximately 400 nm to 780 nm) while micro-LEDs used for tracking may be designed to emit light in the IR band (approximately 780 nm to 2,200 nm). In some embodiments, the tracking micro-LEDs and content micro-LEDs may be simultaneously active. In some embodiments, the tracking micro-LEDs may be controlled to emit tracking light during a time period that content micro-LEDs are deactivated and are thus not displaying content to the user. The AR/VR system can incorporate optics, such as those described above, and/or an AR/VR display, for example to couple light emitted by micro-LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system.

In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

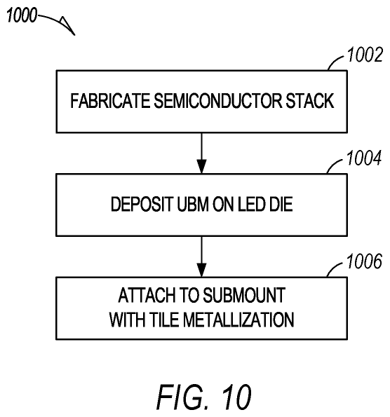

FIG. 10 illustrates an example method of fabricating an illumination, according to some embodiments. Not all of the operations may be undertaken in the method 1000, and/or additional operations may be present.

The operations may occur in a different order from that indicated in FIG. 10.

At operation 1002, a semiconductor stack of the LED structure may be formed via an epitaxial process. The semiconductor stack that includes the n-type and p-type semiconductor layers, as well as the active region therebetween in which light is created through electron-hole recombination processes. In some embodiments, the fabrication of the semiconductor stack may include etching of the n-type semiconductor layer to form fins. The semiconductor stack may be formed in any of a number of geometric shapes, such as rectangular, to provide polarized light emission from one or more sidewalls of the semiconductor stack based on waveguiding within the epitaxial semiconductor layers. The semiconductor stack may be formed on a sapphire or other substrate.

After fabrication of the semiconductor stack, UBM may be deposited at operation 1004. The UBM includes both nUBM and pUBM. At least one of the nUBM or pUBM may be deposited in an L-like shape.

The LED structure may be attached to a submount at operation 1006. The submount may be a PCB or other wafer that contains control and/or driving circuitry, for example, used to control light emission from the LED structure. The submount may include tile metallization that overlaps the nUBM and pUBM and serially connects LED dies together by electrically connecting the nUBM of one of the LED dies to the pUBM of an adjacent LED die. The connection of the tile metallization between the nUBM of one of the LED dies and the pUBM of the adjacent LED die is disposed entirely under (or only under) one of the LED dies. That is, the connection of the tile metallization between the nUBM of one of the LED dies and the pUBM of the adjacent LED die is localized to one of the LED dies. The electrical and thermal interface between the LED UBM and the tile top metallization may be made by a direct contact process (e.g., via thermocompression bonding or another direct bond method) or facilitated by a solder and reflow process.

While the arrangement in some embodiments is designed for electrical serial connection between die, in other embodiments a parallel connection may be used. In a parallel connection all anodes may be electrically connected together, and all cathodes may be electrically connected together.

In addition, while luminance cut-off is a feature of a vehicular low beam lamp, the multi-package LED array described herein may also be used in a high beam lamp in which there is no cut-off.

The embodiments may be directed to large area LED die that is not segmented, and thus where there is no possibility to control the current flowing in each pixel/segment of the die and therefore no strong discontinuity of luminance between different areas of the die but smooth variation instead. In some embodiments, similar techniques may be applied to microLED that include thousands to millions of microscopic LEDs that may emit light and that may be individually controlled or controlled in groups of pixels (e.g., 5×5 groups of pixels). The microLEDs are small (e.g., <0.01 mm on a side) and may provide monochromatic or multi-chromatic light, typically red, green, or yellow using inorganic semiconductor material such as that indicated above. In camera embodiments in which the LED arrays contain segmented LEDs in which the LEDs are divided into a grid of light emitting areas and non-light emitting areas, the effect of the non-light emitting areas on the image captured using the one or more LED arrays may be compensated for by moving the one or more LED arrays and/or at least one lens using one or more actuators during the exposure duration of the scene to shift the LEDs slightly to illuminate the areas of the scene that would be subject to the non-light emitting areas. For array sizes larger than 3×3 matrices, the LED segments may be combined with an integrated driver to allow the function of individual addressability and obtain the small form factor desired for mobile devices without creating issues in layout of the semiconductor layers used to create the integrated devices.

### EXAMPLES

Example 1 is an illumination apparatus comprising: a light-emitting diode (LED) die containing a semiconductor stack that includes, an n-type semiconductor, a p-type semiconductor, and an active region sandwiched between the n-type semiconductor and the p-type semiconductor; and anode under bump metallization (pUBM) electrically coupled to the p-type semiconductor and cathode UBM (nUBM) electrically coupled to the n-type semiconductor, at least one of the pUBM or the nUBM having a substantially L shape.

In Example 2, the subject matter of Example 1 includes, wherein the substantially L shape comprises a relatively smaller rectangular area that extends at or proximate to one end of relatively larger rectangular area in a direction substantially perpendicular to the relatively larger rectangular area.

In Example 3, the subject matter of Example 2 includes, wherein one of the pUBM or the nUBM has the substantially L shape and another of the pUBM or the nUBM has a substantially rectangular shape, and a distance between the one of the pUBM or the nUBM and the other of the pUBM or the nUBM is substantially constant.

In Example 4, the subject matter of Example 3 includes, wherein an overall shape of the one of the pUBM or the nUBM and the other of the pUBM or the nUBM substantially forms a square.

In Example 5, the subject matter of Examples 2-4 includes, a tile on which a tile metallization is formed, the at least one of the pUBM or the nUBM electrically coupled to the tile metallization through the relatively smaller rectangular area via one of direct contact or a solder.

In Example 6, the subject matter of Examples 1-5 includes, another LED die laterally adjacent to the LED die, the other LED die containing another semiconductor stack that includes another n-type semiconductor, another p-type semiconductor, and another active region sandwiched between the other n-type semiconductor and the other p-type semiconductor; and another pUBM electrically coupled to the other p-type semiconductor and another nUBM electrically coupled to the other n-type semiconductor, at least one of the other pUBM or the other nUBM having the substantially L shape and arranged to replicate an arrangement of the LED die.

In Example 7, the subject matter of Example 6 includes, a tile on which a tile metallization is formed, wherein: a first of the pUBM or the nUBM has the substantially L shape and a second of the pUBM or the nUBM has a substantially rectangular shape, a first of the other pUBM or the other nUBM has the substantially L shape and a second of the other pUBM or the other nUBM has the substantially rectangular shape, and the tile metallization electrically couples the LED die and the other LED die together.

In Example 8, the subject matter of Example 7 includes, wherein the first of the pUBM or the nUBM is electrically coupled to the second of the other pUBM or the other nUBM.

In Example 9, the subject matter of Examples 7-8 includes, wherein: the substantially L shape of the first of the pUBM or the nUBM comprises a relatively smaller rectangular area that extends at or proximate to one end of relatively larger rectangular area in a direction substantially perpendicular to the relatively larger rectangular area, and the first of the pUBM or the nUBM is electrically coupled to the tile metallization through the relatively smaller rectangular area of the first of the pUBM or the nUBM.

In Example 10, the subject matter of Example 9 includes, wherein the second of the other pUBM or the other nUBM is electrically coupled to the tile metallization and to the first of the pUBM or the nUBM through an electrical connection between the tile metallization and the relatively smaller rectangular area of the first of the pUBM or the nUBM.

In Example 11, the subject matter of Examples 9-10 includes, wherein an electrical connection between the tile metallization and the relatively smaller rectangular area of the first of the pUBM or the nUBM is localized to the LED die.

In Example 12, the subject matter of Examples 1 -11 includes, one of a printed circuit board (PCB) or ceramic tile on which a tile metallization is formed, the at least one of the pUBM or the nUBM electrically coupled to the tile metallization; and a heat sink coupled to the one of the PCB or ceramic tile through a thermal interface material (TIM), the heat sink configured to dissipate heat from the LED die.

Example 13 is a light-emitting diode (LED) die comprising: a semiconductor stack that includes, an n-type semiconductor, a p-type semiconductor, and an active region sandwiched between the n-type semiconductor and the p-type semiconductor; and anode under bump metallization (pUBM) electrically coupled to the p-type semiconductor and cathode UBM (nUBM) electrically coupled to the n-type semiconductor, at least one of the pUBM or the nUBM having a substantially L shape.

In Example 14, the subject matter of Example 13 includes, wherein the substantially L shape comprises a relatively smaller rectangular area that extends at or proximate to one end of a relatively larger rectangular area in a direction substantially perpendicular to the relatively larger rectangular area.

In Example 15, the subject matter of Example 14 includes, wherein one of the pUBM or the nUBM has the substantially L shape and another of the pUBM or the nUBM has a substantially rectangular shape, and a distance between the one of the pUBM or the nUBM and the other of the pUBM or the nUBM is substantially constant.

In Example 16, the subject matter of Example 15 includes, wherein an overall shape of the one of the pUBM or the nUBM and the other of the pUBM or the nUBM substantially forms a square.

In Example 17, the subject matter of Examples 14-16 includes, one of a printed circuit board (PCB) or ceramic tile on which a tile metallization is formed, the at least one of the pUBM or the nUBM electrically coupled to the tile metallization through the relatively smaller rectangular area.

In Example 18, the subject matter of Example 17 includes, a heat sink coupled to the one of the PCB or ceramic tile through a thermal interface material (TIM), the heat sink configured to dissipate heat from the LED die.

Example 19 is a method of fabricating an illumination device, the method comprising: epitaxially growing, on a substrate of a light emitting diode (LED) die, a semiconductor stack that includes, an n-type semiconductor, a p-type semiconductor, and an active region sandwiched between the n-type semiconductor and the p-type semiconductor; and forming at least one of anode under bump metallization (pUBM) electrically coupled to the p-type semiconductor and cathode UBM (nUBM) electrically coupled to the n-type semiconductor in a substantially L shape.

In Example 20, the subject matter of Example 19 includes, wherein the substantially L shape comprises a relatively smaller rectangular area that extends at or proximate to one end of a relatively larger rectangular area in a direction substantially perpendicular to the relatively larger rectangular area.

In Example 21, the subject matter of Example 20 includes, wherein one of the pUBM or the nUBM has the substantially L shape and another of the pUBM or the nUBM has a substantially rectangular shape, and a distance between the one of the pUBM or the nUBM and the other of the pUBM or the nUBM is substantially constant.

In Example 22, the subject matter of Example 21 includes, wherein an overall shape of the one of the pUBM or the nUBM and the other of the pUBM or the nUBM substantially forms a square.

In Example 23, the subject matter of Examples 20-22 includes, forming a tile metallization on a tile and electrically coupling the at least one of the pUBM or the nUBM to the tile metallization through the relatively smaller rectangular area.

In Example 24, the subject matter of Examples 19-23 includes, disposing another LED die laterally adjacent to the LED die, the other LED die containing another semiconductor stack that includes another n-type semiconductor, another p-type semiconductor, and another active region sandwiched between the other n-type semiconductor and the other p-type semiconductor; and electrically coupling another pUBM to the other p-type semiconductor and another nUBM electrically coupled to the other n-type semiconductor, at least one of the other pUBM or the other nUBM having the substantially L shape and arranged to replicate an arrangement of the LED die.

In Example 25, the subject matter of Example 24 includes, forming a tile metallization on a tile, a first of the pUBM or the nUBM having the substantially L shape and a second of the pUBM or the nUBM having a substantially rectangular shape, a first of the other pUBM or the other nUBM having the substantially L shape and a second of the other pUBM or the other nUBM having the substantially rectangular shape, and electrically coupling the LED die and the other LED die together using the tile metallization.

In Example 26, the subject matter of Example 25 includes, wherein the first of the pUBM or the nUBM is electrically coupled to the second of the other pUBM or the other nUBM.

In Example 27, the subject matter of Examples 25-26 includes, wherein: the substantially L shape of the first of the pUBM or the nUBM comprises a relatively smaller rectangular area that extends at or proximate to one end of a relatively larger rectangular area in a direction substantially perpendicular to the relatively larger rectangular area, and the first of the pUBM or the nUBM is electrically coupled to the tile metallization through the relatively smaller rectangular area of the first of the pUBM or the nUBM.

In Example 28, the subject matter of Example 27 includes, wherein the second of the other pUBM or the other nUBM is electrically coupled to the tile metallization and to the first of the pUBM or the nUBM through an electrical connection between the tile metallization and the relatively smaller rectangular area of the first of the pUBM or the nUBM.

In Example 29, the subject matter of Examples 27-28 includes, wherein an electrical connection between the tile metallization and the relatively smaller rectangular area of the first of the pUBM or the nUBM is localized to the LED die.

In Example 30, the subject matter of Examples 19-29 includes, forming a tile metallization on one of a printed circuit board (PCB) or ceramic tile; electrically coupling the at least one of the pUBM or the nUBM to the tile metallization; and coupling a heat sink to the one of the PCB or ceramic tile through a thermal interface material (TIM) to dissipate heat from the LED die.

Example 31 is at least one machine-readable medium including instructions that, when executed by processing circuitry, cause the processing circuitry to perform operations to implement of any of Examples 1-30.

Example 32 is an apparatus comprising means to implement of any of Examples 1-30.

Example 33 is a system to implement of any of Examples 1-30.

Example 34 is a method to implement of any of Examples 1-30.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. An illumination apparatus comprising:
a light-emitting diode (LED) die containing a semiconductor stack that includes an n-type semiconductor, a p-type semiconductor, and an active region sandwiched between the n-type semiconductor and the p-type semiconductor; and
anode under bump metallization (pUBM) electrically coupled to the p-type semiconductor and cathode UBM (nUBM) electrically coupled to the n-type semiconductor, at least one of the pUBM or the nUBM having a substantially L shape and configured to position a gap between tile metallization partially to beneath the LED die instead of between adjacent LED dies.

2. The illumination apparatus of claim 1, wherein the substantially L shape comprises a relatively smaller rectangular area that extends at or proximate to one end of a relatively larger rectangular area in a direction substantially perpendicular to the relatively larger rectangular area.

3. The illumination apparatus of claim 2, wherein:
one of the pUBM or the nUBM has the substantially L shape,
another of the pUBM or the nUBM has a substantially rectangular shape, and
a distance between the one of the pUBM or the nUBM and the other of the pUBM or the nUBM is substantially constant.

4. The illumination apparatus of claim 3, wherein an overall shape of the one of the pUBM or the nUBM and the other of the pUBM or the nUBM substantially forms a square.

5. The illumination apparatus of claim 2, further comprising a tile on which a tile metallization is formed, the at least one of the pUBM or the nUBM electrically coupled to the tile metallization through the relatively smaller rectangular area.

6. The illumination apparatus of claim 1, further comprising:
another LED die laterally adjacent to the LED die, the other LED die containing another semiconductor stack that includes another n-type semiconductor, another p-type semiconductor, and another active region sandwiched between the other n-type semiconductor and the other p-type semiconductor; and
another pUBM electrically coupled to the other p-type semiconductor and another nUBM electrically coupled to the other n-type semiconductor, at least one of the other pUBM or the other nUBM having the substantially L shape and arranged to replicate an arrangement of the LED die.

7. The illumination apparatus of claim 6, further comprising a tile on which a tile metallization is formed, wherein:
a first of the pUBM or the nUBM has the substantially L shape and a second of the pUBM or the nUBM has a substantially rectangular shape,
a first of the other pUBM or the other nUBM has the substantially L shape and a second of the other pUBM or the other nUBM has the substantially rectangular shape, and
the tile metallization electrically couples the LED die and the other LED die together.

8. The illumination apparatus of claim 7, wherein the first of the pUBM or the nUBM is electrically coupled to the second of the other pUBM or the other nUBM.

9. The illumination apparatus of claim 7, wherein:
the substantially L shape of the first of the pUBM or the nUBM comprises a relatively smaller rectangular area that extends at or proximate to one end of a relatively larger rectangular area in a direction substantially perpendicular to the relatively larger rectangular area, and
the first of the pUBM or the nUBM is electrically coupled to the tile metallization through the relatively smaller rectangular area of the first of the pUBM or the nUBM.

10. The illumination apparatus of claim 9, wherein the second of the other pUBM or the other nUBM is electrically coupled to the tile metallization and to the first of the pUBM or the nUBM through an electrical connection between the tile metallization and the relatively smaller rectangular area of the first of the pUBM or the nUBM.

11. The illumination apparatus of claim 9, wherein an electrical connection between the tile metallization and the relatively smaller rectangular area of the first of the pUBM or the nUBM is localized to the LED die.

12. The illumination apparatus of claim 1, further comprising:
one of a printed circuit board (PCB) or ceramic tile on which a tile metallization is formed, the at least one of the pUBM or the nUBM electrically coupled to the tile metallization; and
a heat sink coupled to the one of the PCB or ceramic tile through a thermal interface material (TIM), the heat sink configured to dissipate heat from the LED die.

13. A light-emitting diode (LED) die comprising:
a semiconductor stack that includes an n-type semiconductor, a p-type semiconductor, and an active region sandwiched between the n-type semiconductor and the p-type semiconductor; and
anode under bump metallization (pUBM) electrically coupled to the p-type semiconductor and cathode UBM (nUBM) electrically coupled to the n-type semiconductor, at least one of the pUBM or the nUBM having a substantially L shape and configured to position a gap between tile metallization partially to beneath the LED die instead of between adjacent LED dies.

14. The LED die of claim 13, wherein the substantially L shape comprises a relatively smaller rectangular area that extends at or proximate to one end of a relatively larger rectangular area in a direction substantially perpendicular to the relatively larger rectangular area.

15. The LED die of claim 14, wherein one of the pUBM or the nUBM has the substantially L shape and another of the pUBM or the nUBM has a substantially rectangular shape, and a distance between the one of the pUBM or the nUBM and the other of the pUBM or the nUBM is substantially constant.

16. The LED die of claim 14, further comprising one of a printed circuit board (PCB) or ceramic tile on which a tile metallization is formed, the at least one of the pUBM or the nUBM electrically coupled to the tile metallization through the relatively smaller rectangular area.

17. The LED die of claim 16, further comprising a heat sink coupled to the one of the PCB or ceramic tile through a thermal interface material (TIM), the heat sink configured to dissipate heat from the LED die.

18. A method of fabricating an illumination device, the method comprising:
epitaxially growing, on a substrate of a light emitting diode (LED) die, a semiconductor stack that includes an n-type semiconductor, a p-type semiconductor, and an active region sandwiched between the n-type semiconductor and the p-type semiconductor; and
forming at least one of anode under bump metallization (pUBM) electrically coupled to the p-type semiconductor and cathode UBM (nUBM) electrically coupled to the n-type semiconductor in a substantially L shape and configured to position a gap between tile metallization partially to beneath the LED die instead of between adjacent LED dies.

19. The method of claim 18, wherein the substantially L shape comprises a relatively smaller rectangular area that extends at or proximate to one end of a relatively larger rectangular area in a direction substantially perpendicular to the relatively larger rectangular area.

20. The method of claim 19, wherein one of the pUBM or the nUBM has the substantially L shape and another of the pUBM or the nUBM has a substantially rectangular shape, and a distance between the one of the pUBM or the nUBM and the other of the pUBM or the nUBM is substantially constant.
